(19) United States
(12) Patent Application Publication
(10) Pub. No.: US 2011/0057130 A1
(43) Pub. Date: Mar. 10, 2011

(54) FLIP-CHIP TYPE IMAGE-CAPTURING MODULE

(76) Inventors: Chi-Hsing HSU, Taipei (TW); Chih-Chien Chen, Taipei (TW)

(21) Appl. No.: 12/686,776

(22) Filed: Jan. 13, 2010

(30) Foreign Application Priority Data
Sep. 9, 2009 (TW) 98216629

(51) Int. Cl. H01L 31/14

(52) U.S. Cl. 250/552

(57) ABSTRACT

A flip-chip type image-capturing module includes a light-transmitting substrate unit, an image-capturing unit, a light-emitting unit, and a light beam guiding unit. The image-capturing unit has an image-capturing element electrically disposed on a bottom surface of the light-transmitting substrate unit by a plurality of conductive elements. The image-capturing element has an image-sensing area formed on a top surface thereof and facing the light-transmitting substrate unit. The light-emitting unit has a light-emitting element electrically disposed on the light-transmitting substrate unit. The light beam guiding unit is disposed on the top surface of the light-transmitting substrate unit, and an object is disposed on the light beam guiding unit. The light beam guiding unit has a light beam guiding structure for guiding light beams generated by the light-emitting element to a bottom portion of the object and the image-sensing area of the image-capturing element in sequence.

### BACKGROUND OF THE INVENTION

1. Field of the Invention

The present invention relates to an image-capturing module, in particular, to a flip-chip type image-capturing module.

2. Description of Related Art

A personal fingerprint is a unique bio-feature different from those of others. When used as a personal secret code, it is extremely secure. Because of the popularity of electronic device and the increase of their storage capacities, the protection for personal data stored therein becomes increasingly important. Using a fingerprint for unlocking electronic device or as a secret code can make management of personal data more efficient. Electronic device such as a mobile phone, a computer host, and various kinds of computer peripherals can make use of a fingerprint scanning device to capture a user's fingerprint for identity confirmation. After the fingerprint image in the fingerprint scanning device is converted into digital fingerprint information, it is easy to transmit the digital fingerprint information to a controller in the electronic device to exploit fully the effect of fingerprint identification.

Referring to FIG. 1, the prior art provides an image-capturing module including a PCB P, an image sensor S electrically disposed on the PCB P, an LED D electrically disposed on the PCB P, a condensing lens G disposed above the image sensor S, and a light-guiding element T disposed above the LED D. The image capturing process of the prior art is shown as follows: (1) light beams L generated by the LED D are guided by the light-guiding element T to form a projecting light beams L′ that project onto the object F above the condensing lens G; next (2) the projecting light beams L′ are reflected by the object F to form reflecting light beams L″ that project onto the condensing lens G; and then (3) the reflecting light beams L″ pass through the condensing lens G and project onto the image sensor S in order to capture the image information of one surface of the object F.

### SUMMARY OF THE INVENTION

In view of the aforementioned issues, the present invention provides a flip-chip type image-capturing module in order to decrease the whole thickness.

To achieve the above-mentioned objectives, the present invention provides a flip-chip type image-capturing module, including: a light-transmitting substrate unit, an image-capturing unit, an optical imaging unit, a light-guiding unit, a light-emitting unit and a cover unit. The image-capturing unit has at least one image-capturing element electrically disposed on a bottom surface of the light-transmitting substrate unit by a plurality of conductive elements, wherein the at least one image-capturing element has an image-sensing area formed on a top surface thereof The optical imaging unit is disposed on a top surface of the light-transmitting substrate unit and above the at least one image-capturing element. The light-guiding unit is disposed on the top surface of the light-transmitting substrate unit and covering the optical imaging unit. The light-emitting unit has at least one light-emitting element electrically disposed on the light-transmitting substrate unit, wherein the at least one light-emitting element has a light-emitting area facing the light-guiding unit. The cover unit is disposed on the top surface of the light-transmitting substrate unit and covering the light-guiding unit, wherein the cover unit has a light-transmitting area formed on a top side thereof and above the at least one image-capturing element.

Therefore, light beams generated from the light-emitting area of the at least one light-emitting element are projected onto the light-guiding unit, then the light beams are guided to project onto an object that is disposed on the light-transmitting area of the cover unit by the light-guiding unit, next the light beams are reflected by the object to form a reflected light beams that are projected onto the optical imaging element, and then the reflected light beams pass through the optical image unit and the light-transmitting substrate unit and project onto the image-sensing area of the at least one image-capturing element.

To achieve the above-mentioned objectives, the present invention provides a flip-chip type image-capturing module, including: a non-light-transmitting substrate unit, an image-capturing unit, an optical imaging unit, a light-guiding unit, a light-emitting unit and a cover unit. The non-light-transmitting substrate unit has at least one first opening. The image-capturing unit has at least one image-capturing element electrically disposed on a bottom surface of the non-light-transmitting substrate unit by a plurality of conductive elements, wherein the at least one image-capturing element has an image-sensing area formed on a top surface thereof and facing the at least one first opening. The optical imaging unit is disposed on a top surface of the non-light-transmitting substrate unit and above the at least one image-capturing element. The light-guiding unit is disposed on the top surface of the non-light-transmitting substrate unit and covering the optical imaging unit. The light-emitting unit has at least one light-emitting element electrically disposed on the non-light-transmitting substrate unit, wherein the at least one light-emitting element has a light-emitting area facing the light-guiding unit. The cover unit is disposed on the top surface of the non-light-transmitting substrate unit and covering the light-guiding unit, wherein the cover unit has a non-light-transmitting area formed on a top side thereof and above the at least one image-capturing element.

Therefore, light beams generated from the light-emitting area of the at least one light-emitting element are projected onto the light-guiding unit, then the light beams are guided to project onto an object that is disposed on the non-light-transmitting area of the cover unit by the light-guiding unit, next the light beams are reflected by the object to form a reflected light beams that are projected onto the optical imaging element, and then the reflected light beams pass through the optical image unit and the at least one first opening of the non-light-transmitting substrate unit and project onto the image-sensing area of the at least one image-capturing element.

To achieve the above-mentioned objectives, the present invention provides a flip-chip type image-capturing module, including: a light-transmitting substrate unit, an image-capturing unit, a light-emitting unit, and a light beam guiding unit. The image-capturing unit has at least one image-capturing element electrically disposed on a bottom surface of the light-transmitting substrate unit by a plurality of conductive elements, wherein the at least one image-capturing element has an image-sensing area formed on a top surface thereof and facing the light-transmitting substrate unit. The light-emitting unit has at least one light-emitting element electrically disposed on the light-transmitting substrate unit. The light beam guiding unit is disposed on the top surface of the light-transmitting substrate unit, wherein an object is disposed on the light beam guiding unit, and the light beam guiding unit has a light beam guiding structure for guiding light beams generated by the at least one light-emitting element to a bottom portion of the object and the image-sensing area of the at least one image-capturing element in sequence.

Hence, the present invention places the image-capturing element to be electrically disposed on the bottom surface of the light-transmitting substrate or the non-light-transmitting substrate with the first opening by a flip-chip method in order to decrease the whole thickness of the image-capturing module. In other words, the whole thickness of optical elements applied to the image-capturing module of the present invention may be decreased.

In order to further understand the techniques, means and effects the present invention takes for achieving the prescribed objectives, the following detailed descriptions and appended drawings are hereby referred, such that, through which, the purposes, features and aspects of the present invention may be thoroughly and concretely appreciated; however, the appended drawings are provided solely for reference and illustration, without any intention that they be used for limiting the present invention.

### BRIEF DESCRIPTION OF THE DRAWINGS

FIG. 1 is a schematic view of the image-capturing module according to the prior art;

FIG. 2 is a cross-sectional, schematic view of the flip-chip type image-capturing module according to the first embodiment of the present invention;

FIG. 3 is a cross-sectional, schematic view of the flip-chip type image-capturing module according to the second embodiment of the present invention;

FIG. 4 is a cross-sectional, schematic view of the flip-chip type image-capturing module according to the third embodiment of the present invention;

FIG. 5 is a cross-sectional, schematic view of the flip-chip type image-capturing module according to the fourth embodiment of the present invention;

FIG. 6 is a cross-sectional, schematic view of the flip-chip type image-capturing module according to the fifth embodiment of the present invention;

FIG. 7 is a cross-sectional, schematic view of the flip-chip type image-capturing module according to the sixth embodiment of the present invention;

FIG. 8 is a cross-sectional, schematic view of the flip-chip type image-capturing module according to the seventh embodiment of the present invention; and

FIG. 9 is a cross-sectional, schematic view of the flip-chip type image-capturing module according to the eighth embodiment of the present invention.

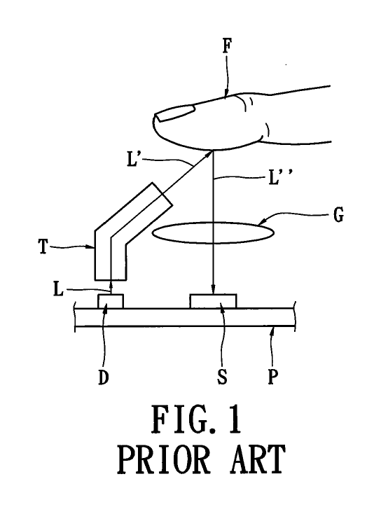

### DETAILED DESCRIPTION OF THE PREFERRED EMBODIMENTS

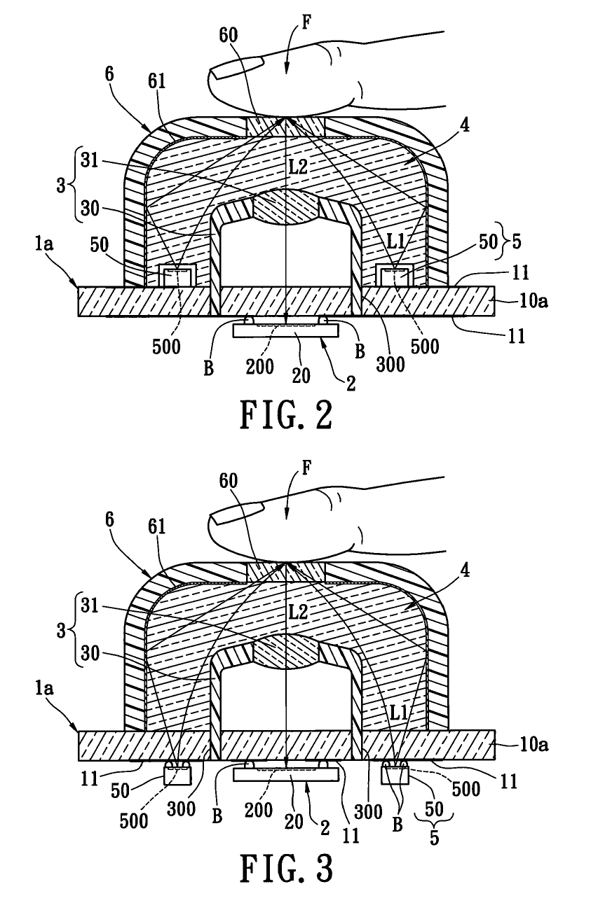

Referring to FIG. 2, the first embodiment of the present invention provides a flip-chip type image-capturing module, including: a light-transmitting substrate unit 1a, an image-capturing unit 2, an optical imaging unit 3, a light-guiding unit 4, a light-emitting unit 5 and a cover unit 6.

The light-transmitting substrate unit 1 a has a light-transmitting substrate 10a and a plurality of conductive circuits 11 disposed on the light-transmitting substrate 10a, and the image-capturing unit 2 and the light-emitting unit 5 electrically connected to the conductive circuits 11. In other words, the present invention can form the conductive circuits 11 on the light-transmitting substrate 10a, so that the light-transmitting substrate 10a has two functions of translucency and electric conduction. Hence, the light-transmitting substrate unit 1a may be a light-transmitting PCB. In addition, the light-transmitting substrate 10a may be composed of a light-transmitting portion above the image-capturing unit 2 and two opaque flexible or hard portions under the light-emitting unit 5 according to different design requirements.

Moreover, the image-capturing unit 2 has at least one image-capturing element 20 (so that the number of the image-capturing element is adjustable) electrically disposed on a bottom surface of the light-transmitting substrate unit 1a by a plurality of conductive elements B such as solder balls or solder glue. Hence, the image-capturing element 20 is electrically disposed on the bottom surface of the light-transmitting substrate unit 1a by a flip-chip method. The image-capturing element 20 may be an image sensor, and the image-capturing element 20 can electrically connect to analysis software in computer in order to read image information that is captured by the image-capturing element 20. In addition, the image-capturing element 20 has an image-sensing area 200 formed on a top surface thereof and facing the optical imaging unit 3, and the image-capturing element 20 is electrically connected to the conductive circuits 11 by the conductive elements B.

Furthermore, the optical imaging unit 3 with anti stray light function is disposed on a top surface of the light-transmitting substrate unit 1a and above the image-capturing element 20. In the first embodiment, the optical imaging unit 3 has a shading body 30 (for example, a shading layer is coated on the external surface of the shading body 30 in order to achieve anti stray light function) positioned on the top surface of the light-transmitting substrate unit 1a and a condensing element 31 (such as a condensing lens for condensing light beams) jointed with the shading body 30 and disposed above the image-capturing element 20. The shading body 30 and the condensing element 31 may be integrally formed in one piece. Hence, the light beams are projected onto the image-capturing element 20 along a predetermined path by using the optical image unit 3 (it means the optical image unit 3 can shade other external stray light), so that the image-capturing element 20 can obtain correct image information.

In addition, the light-guiding unit 4 is disposed on the top surface of the light-transmitting substrate unit 1a and covering the optical imaging unit 3. The light-guiding unit 4 may be a light-transmitting light-guiding element made of plastic or glass material of high light-guiding efficiency, so that the light beams L1 generated by the light-emitting unit 5 may be guided to a destination according to the design shape of the light-guiding unit 4. In other words, the light beams L1 generated by the light-emitting unit 5 may be guided and projected onto an object F by using the light-guiding unit 4. Furthermore, the light-guiding unit 4 may be combined with the condensing element 31 according to different design requirements.

Moreover, the light-emitting unit 5 has at least one light-emitting element 50 (the first embodiment discloses two light-emitting elements 50) electrically disposed on the top surface of the light-transmitting substrate unit 1a. Each light-emitting element 50 has a light-emitting area 500 facing the light-guiding unit 4, and each light-emitting element 50 is electrically connected to the conductive circuits 11. In addition, each light-emitting element 50 may be an LED. However, the above-mentioned definition of each light-emitting element 50 is just an example, so that any type of light-emitting element may be applied to the present invention.

Furthermore, the shading body 30 of the optical imaging unit 3 has a shading plate 300 inserted into the light-transmitting substrate 10a of the light-transmitting substrate unit 1a in order to prevent the light beams L1 generated by the two light-emitting elements 50 from passing through the light-transmitting substrate unit 1a to be guided to the image-capturing element 20 directly. In other words, the shading plate 300 is extended from the bottom of the shading body 30 in order to shade optical path that is generated in the light-transmitting substrate 10a and between each light-emitting element 50 and the image-capturing element 20, so that the shading body 30 can prevent the light beams L1 generated by the two light-emitting elements 50 from passing through the light-transmitting substrate unit 1a to be guided to the image-capturing element 20 directly.

In addition, the cover unit 6 is disposed on the top surface of the light-transmitting substrate unit 1a and covering the light-guiding unit 4. The cover unit 6 has a light-transmitting area 60 such as a lens or glass formed on a top side thereof and above the image-capturing element 20 (or above the condensing element 31), and the cover unit 6 has a reflecting layer 61 formed on an inner surface thereof in order to reflect the light beams. In the first embodiment, the light-transmitting area 60 of the cover unit 6 may be a light-transmitting element (such as transparent glass) disposed above the condensing element 31 and the sensing surface of the object F (such as fingerprint of finger) may be disposed on the light-transmitting element (the light-transmitting area 60) to be sensed. Furthermore, the reflecting layer 61 may be a reflecting element adhered to the inner surface of the cover unit 6 or a reflecting film coated on the inner surface of the cover unit 6 according to different requirements.

Therefore, the light beams L1 generated from the two light-emitting areas 500 of the two light-emitting elements 50 are projected onto the light-guiding unit 4, then the light beams L1 are guided to project onto the object F that is disposed on the light-transmitting area 60 of the cover unit 6 by the light-guiding unit 4 as shown in FIG. 2, next the light beams L1 are reflected by the object F to form a reflected light beams L2 that are projected onto the optical imaging element 3, and then the reflected light beams L2 pass through the condensing element 31 of the optical image unit 3 and the light-transmitting substrate 10a of the light-transmitting substrate unit 1a and project onto the image-sensing area 200 of the image-capturing element 20 in order to capture the image information of one surface of the object F.

Referring to FIG. 3, the second embodiment of the present invention provides a flip-chip type image-capturing module, including: a light-transmitting substrate unit 1a, an image-capturing unit 2, an optical imaging unit 3, a light-guiding unit 4, a light-emitting unit 5 and a cover unit 6. The difference between the second embodiment and the first embodiment is that: in the second embodiment, the two light-emitting elements 50 are electrically disposed on the bottom surface of the light-transmitting substrate 10a of the light-transmitting substrate unit 1a by another conductive elements B, so that the light beams L1 generated from the two light-emitting areas 500 of the two light-emitting elements 50 pass through the light-transmitting substrate 10a of the light-transmitting substrate unit 1a to project onto the light-guiding unit 4, then the light beams L1 are guided to project onto the object F that is disposed on the light-transmitting area 60 of the cover unit 6 by the light-guiding unit 4 as shown in FIG. 2, next the light beams L1 are reflected by the object F to form a reflected light beams L2 that are projected onto the optical imaging element 3, and then the reflected light beams L2 pass through the condensing element 31 of the optical image unit 3 and the light-transmitting substrate 10a of the light-transmitting substrate unit 1a and project onto the image-sensing area 200 of the image-capturing element 20 in order to capture the image information of one surface of the object F.

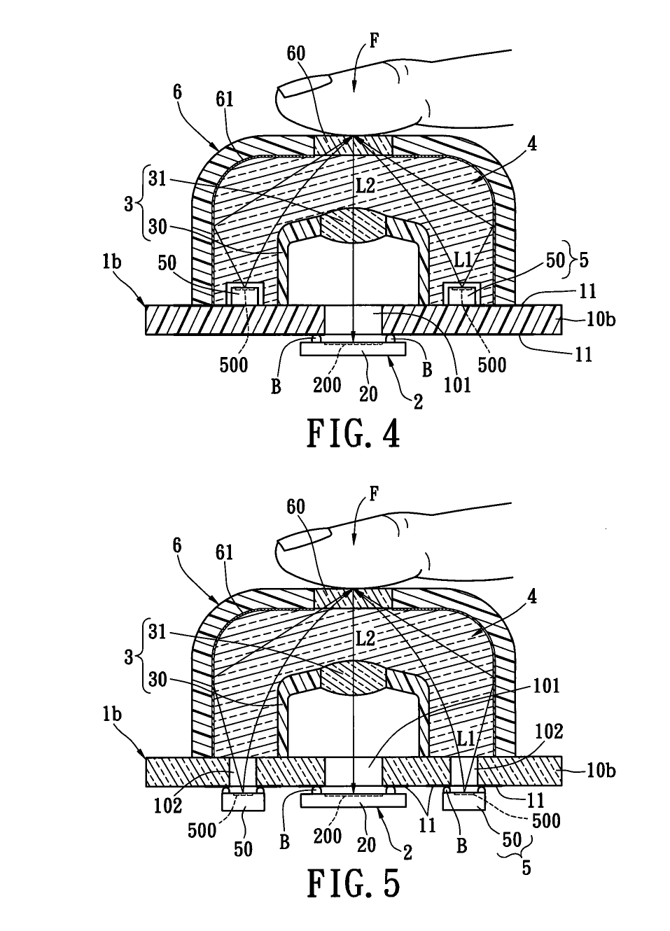

Referring to FIG. 4, the third embodiment of the present invention provides a flip-chip type image-capturing module, including: a non-light-transmitting substrate unit 1b, an image-capturing unit 2, an optical imaging unit 3, a light-guiding unit 4, a light-emitting unit 5 and a cover unit 6.

The non-light-transmitting substrate unit 1b has at least one first opening 101, and the non-light-transmitting substrate unit 1b has a non-light-transmitting substrate 10b and a plurality of conductive circuits 11 disposed on the non-light-transmitting substrate 10b. The image-capturing unit 2 and the light-emitting unit 5 electrically connected to the conductive circuits 11. In other words, the present invention can form the conductive circuits 11 on the non-light-transmitting substrate 10b, so that the non-light-transmitting substrate 10b has two functions of translucency and electric conduction. Hence, the non-light-transmitting substrate unit 1b may be a light-transmitting PCB.

Moreover, the image-capturing unit 2 has at least one image-capturing element 20 (so that the number of the image-capturing element is adjustable) electrically disposed on a bottom surface of the non-light-transmitting substrate unit 1b by a plurality of conductive elements B such as solder balls or solder glue. Hence, the image-capturing element 20 is electrically disposed on the bottom surface of the non-light-transmitting substrate unit 1b by a flip-chip method. The image-capturing element 20 may be an image sensor, and the image-capturing element 20 can electrically connect to analysis software in computer in order to read image information that is captured by the image-capturing element 20. In addition, the image-capturing element 20 has an image-sensing area 200 formed on a top surface thereof and facing the at least one first opening 101, and the image-capturing element 20 is electrically connected to the conductive circuits 11 by the conductive elements B.

Furthermore, the optical imaging unit 3 with anti stray light function is disposed on a top surface of the non-light-transmitting substrate unit 1b and above the image-capturing element 20. In the third embodiment, the optical imaging unit 3 has a shading body 30 (for example, a shading layer is coated on the external surface of the shading body 30 in order to achieve anti stray light function) positioned on the top surface of the non-light-transmitting substrate unit 1b and a condensing element 31 (such as a condensing lens for condensing light beams) jointed with the shading body 30 and disposed above the image-capturing element 20. The shading body 30 and the condensing element 31 may be integrally formed in one piece. Hence, the light beams are projected onto the image-capturing element 20 along a predetermined path by using the optical image unit 3 (it means the optical image unit 3 can shade other external stray light), so that the image-capturing element 20 can obtain correct image information.

In addition, the light-guiding unit 4 is disposed on the top surface of the non-light-transmitting substrate unit 1b and covering the optical imaging unit 3. The light-guiding unit 4 may be a light-transmitting light-guiding element made of plastic or glass material of high light-guiding efficiency, so that the light beams L1 generated by the light-emitting unit 5 may be guided to a destination according to the design shape of the light-guiding unit 4. In other words, the light beams L1 generated by the light-emitting unit 5 may be guided and projected onto an object F by using the light-guiding unit 4.

Moreover, the light-emitting unit 5 has at least one light-emitting element 50 (the third embodiment discloses two light-emitting elements 50) electrically disposed on the top surface of the non-light-transmitting substrate unit 1b. Each light-emitting element 50 has a light-emitting area 500 facing the light-guiding unit 4, and each light-emitting element 50 is electrically connected to the conductive circuits 11. In addition, each light-emitting element 50 may be an LED. However, the above-mentioned definition of each light-emitting element 50 is just an example, so that any type of light-emitting element may be applied to the present invention.

In addition, the cover unit 6 is disposed on the top surface of the non-light-transmitting substrate unit 1b and covering the light-guiding unit 4. The cover unit 6 has a light-transmitting area 60 formed on a top side thereof and above the image-capturing element 20 (or above the condensing element 31), and the cover unit 6 has a reflecting layer 61 formed on an inner surface thereof in order to reflect the light beams. In the third embodiment, the light-transmitting area 60 of the cover unit 6 may be a light-transmitting element (such as transparent glass) disposed above the condensing element 31 and the sensing surface of the object F (such as fingerprint of finger) may be disposed on the light-transmitting element (the light-transmitting area 60) to be sensed. Furthermore, the reflecting layer 61 may be a reflecting element adhered to the inner surface of the cover unit 6 or a reflecting film coated on the inner surface of the cover unit 6 according to different requirements.

Therefore, the light beams L1 generated from the two light-emitting areas 500 of the two light-emitting elements 50 are projected onto the light-guiding unit 4, then the light beams L1 are guided to project onto the object F that is disposed on the light-transmitting area 60 of the cover unit 6 by the light-guiding unit 4 as shown in FIG. 4, next the light beams L1 are reflected by the object F to form a reflected light beams L2 that are projected onto the optical imaging element 3, and then the reflected light beams L2 pass through the condensing element 31 of the optical image unit 3 and the at least one first opening 101 of the non-light-transmitting substrate unit 1b and project onto the image-sensing area 200 of the image-capturing element 20 in order to capture the image information of one surface of the object F.

Referring to FIG. 5, the fourth embodiment of the present invention provides a flip-chip type image-capturing module, including: a light-transmitting substrate unit 1a, an image-capturing unit 2, an optical imaging unit 3, a light-guiding unit 4, a light-emitting unit 5 and a cover unit 6. The difference between the fourth embodiment and the third embodiment is that: in the fourth embodiment, the non-light-transmitting substrate unit 1b has at least one second opening 102 (the fourth embodiment discloses two second opening 102), the two light-emitting elements 50 are electrically disposed on the bottom surface of the non-light-transmitting substrate 10b of the non-light-transmitting substrate unit 1b by another conductive elements B, and the two light-emitting areas 500 of the two light-emitting elements 50 respectively face the two second openings 102 of the non-light-transmitting substrate unit 1b.

Therefore, the light beams L1 generated from the two light-emitting areas 500 of the two light-emitting elements 50 respectively pass through the two second openings 102 of the non-light-transmitting substrate unit 1b to project onto the light-guiding unit 4, then the light beams L1 are guided to project onto the object F that is disposed on the light-transmitting area 60 of the cover unit 6 by the light-guiding unit 4 as shown in FIG. 4, next the light beams L1 are reflected by the object F to form a reflected light beams L2 that are projected onto the optical imaging element 3, and then the reflected light beams L2 pass through the condensing element 31 of the optical image unit 3 and the at least one first opening 101 of the non-light-transmitting substrate unit 1b and project onto the image-sensing area 200 of the image-capturing element 20 in order to capture the image information of one surface of the object F.

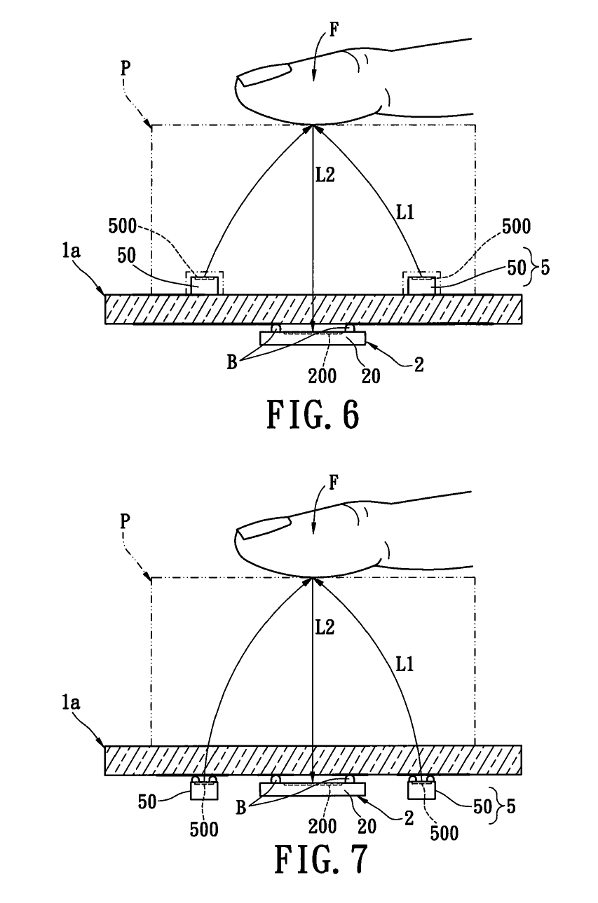

Referring to FIG. 6, the fifth embodiment of the present invention provides a flip-chip type image-capturing module, including: a light-transmitting substrate unit 1a, an image-capturing unit 2, a light-emitting unit 5 and a light beam guiding unit. The feature of the fifth embodiment is that: the image-capturing unit 2 has at least one image-capturing element 20 electrically disposed on a bottom surface of the light-transmitting substrate unit 1a by a plurality of conductive elements B such as solder balls or solder glue. Hence, the image-capturing element 20 is electrically disposed on the bottom surface of the light-transmitting substrate unit 1a by a flip-chip method. In addition, the light beams L1 generated from the two light-emitting areas 500 (the two light-emitting areas 500 faces the light beam guiding unit) of the two light-emitting elements 50 project onto the light beam guiding structure directly.

The difference between the fifth embodiment and the first embodiment is that: in the fifth embodiment, the light beam guiding unit is disposed on the top surface of the light-transmitting substrate unit 1a, and an object F is disposed on the light beam guiding unit. In addition, the light beam guiding unit has a light beam guiding structure P for guiding the light beams L1 generated by the at least one light-emitting element 50 to a bottom portion of the object F (at the same time, the light beams L1 are reflected by the object F to form reflected light beams L2) and the image-sensing area 200 of the at least one image-capturing element 20 in sequence. In other words, any light beam guiding structure P that can guide the light beams L1 generated by the light-emitting element 50 to the bottom portion of the object F and the image-sensing area 200 of the image-capturing element 20 in sequence is applied to the fifth embodiment. For example, the light beam guiding structure P may be composed of the optical imaging unit 3, the light-guiding unit 4 and the cover unit 6 as shown in the first embodiment.

Referring to FIG. 7, the sixth embodiment of the present invention provides a flip-chip type image-capturing module, including: a light-transmitting substrate unit 1a, an image-capturing unit 2, a light-emitting unit 5 and a light beam guiding unit. The feature of the sixth embodiment is that: the image-capturing unit 2 has at least one image-capturing element 20 electrically disposed on a bottom surface of the light-transmitting substrate unit 1a by a plurality of conductive elements B such as solder balls or solder glue. Hence, the image-capturing element 20 is electrically disposed on the bottom surface of the light-transmitting substrate unit 1a by a flip-chip method. In addition, the light beams L1 generated from the two light-emitting areas 500 of the two light-emitting elements 50 pass through the light-transmitting substrate unit 1a to project onto the light beam guiding unit.

The difference between the sixth embodiment and the second embodiment is that: in the sixth embodiment, the light beam guiding unit is disposed on the top surface of the light-transmitting substrate unit 1a, and an object F is disposed on the light beam guiding unit. In addition, the light beam guiding unit has a light beam guiding structure P for guiding the light beams L1 generated by the at least one light-emitting element 50 to a bottom portion of the object F (at the same time, the light beams L1 are reflected by the object F to form reflected light beams L2) and the image-sensing area 200 of the at least one image-capturing element 20 in sequence. In other words, any light beam guiding structure P that can guide the light beams L1 generated by the light-emitting element 50 to the bottom portion of the object F and the image-sensing area 200 of the image-capturing element 20 in sequence is applied to the sixth embodiment. For example, the light beam guiding structure P may be composed of the optical imaging unit 3, the light-guiding unit 4 and the cover unit 6 as shown in the second embodiment.

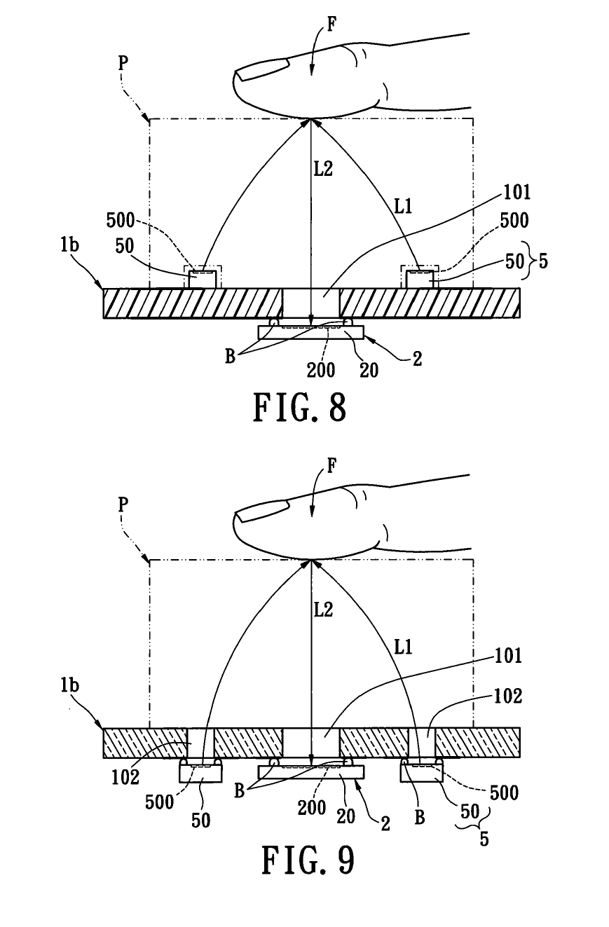

Referring to FIG. 8, the seventh embodiment of the present invention provides a flip-chip type image-capturing module, including: a non-light-transmitting substrate unit 1b, an image-capturing unit 2, a light-emitting unit 5 and a light beam guiding unit. The feature of the seventh embodiment is that: the image-capturing unit 2 has at least one image-capturing element 20 (the image-capturing element 20 has an image-sensing area 200 formed on a top surface thereof and facing the first opening 101) electrically disposed on a bottom surface of the non-light-transmitting substrate unit 1b by a plurality of conductive elements B such as solder balls or solder glue. Hence, the image-capturing element 20 is electrically disposed on the bottom surface of the non-light-transmitting substrate unit 1b by a flip-chip method. In addition, the light beams L1 generated from the two light-emitting areas 500 of the two light-emitting elements 50 project onto the light beam guiding unit.

The difference between the seventh embodiment and the third embodiment is that: in the seventh embodiment, the light beam guiding unit is disposed on the top surface of the non-light-transmitting substrate unit 1b, and an object F is disposed on the light beam guiding unit. In addition, the light beam guiding unit has a light beam guiding structure P for guiding the light beams L1 generated by the at least one light-emitting element 50 to a bottom portion of the object F (at the same time, the light beams L1 are reflected by the object F to form reflected light beams L2) and the image-sensing area 200 of the at least one image-capturing element 20 in sequence. In other words, any light beam guiding structure P that can guide the light beams L1 generated by the light-emitting element 50 to the bottom portion of the object F and the image-sensing area 200 of the image-capturing element 20 in sequence is applied to the seventh embodiment. For example, the light beam guiding structure P may be composed of the optical imaging unit 3, the light-guiding unit 4 and the cover unit 6 as shown in the third embodiment.

Referring to FIG. 9, the eighth embodiment of the present invention provides a flip-chip type image-capturing module, including: a non-light-transmitting substrate unit 1b, an image-capturing unit 2, a light-emitting unit 5 and a light beam guiding unit. The feature of the eighth embodiment is that: the image-capturing unit 2 has at least one image-capturing element 20 (the image-capturing element 20 has an image-sensing area 200 formed on a top surface thereof and facing the first opening 101) electrically disposed on a bottom surface of the non-light-transmitting substrate unit 1b by a plurality of conductive elements B such as solder balls or solder glue. Hence, the image-capturing element 20 is electrically disposed on the bottom surface of the non-light-transmitting substrate unit 1b by a flip-chip method. In addition, the light beams L1 generated from the two light-emitting areas 500 of the two light-emitting elements 50 respectively pass through the two second openings 102 to project onto the light beam guiding unit.

The difference between the eighth embodiment and the fourth embodiment is that: in the eighth embodiment, the light beam guiding unit is disposed on the top surface of the non-light-transmitting substrate unit 1b, and an object F is disposed on the light beam guiding unit. In addition, the light beam guiding unit has a light beam guiding structure P for guiding the light beams L1 generated by the at least one light-emitting element 50 to a bottom portion of the object F (at the same time, the light beams L1 are reflected by the object F to form reflected light beams L2) and the image-sensing area 200 of the at least one image-capturing element 20 in sequence. In other words, any light beam guiding structure P that can guide the light beams L1 generated by the light-emitting element 50 to the bottom portion of the object F and the image-sensing area 200 of the image-capturing element 20 in sequence is applied to the eighth embodiment. For example, the light beam guiding structure P may be composed of the optical imaging unit 3, the light-guiding unit 4 and the cover unit 6 as shown in the fourth embodiment.

In conclusion, the present invention places the image-capturing element 20 to be electrically disposed on the bottom surface of the light-transmitting substrate 10a or the non-light-transmitting substrate 10b with the first opening 101 by a flip-chip method in order to decrease the whole thickness of the image-capturing module. In other words, the whole thickness of optical elements applied to the image-capturing module of the present invention may be decreased.

The above-mentioned descriptions merely represent solely the preferred embodiments of the present invention, without any intention or ability to limit the scope of the present invention which is fully described only within the following claims. Various equivalent changes, alterations or modifications based on the claims of present invention are all, consequently, viewed as being embraced by the scope of the present invention.

What is claimed is:

1. A flip-chip type image-capturing module, comprising:
a light-transmitting substrate unit;
an image-capturing unit having at least one image-capturing element electrically disposed on a bottom surface of the light-transmitting substrate unit by a plurality of conductive elements, wherein the at least one image-capturing element has an image-sensing area formed on a top surface thereof;
an optical imaging unit disposed on a top surface of the light-transmitting substrate unit and above the at least one image-capturing element;
a light-guiding unit disposed on the top surface of the light-transmitting substrate unit and covering the optical imaging unit;
a light-emitting unit having at least one light-emitting element electrically disposed on the light-transmitting substrate unit, wherein the at least one light-emitting element has a light-emitting area facing the light-guiding unit; and
a cover unit disposed on the top surface of the light-transmitting substrate unit and covering the light-guiding unit, wherein the cover unit has a light-transmitting area formed on a top side thereof and above the at least one image-capturing element;
whereby, light beams generated from the light-emitting area of the at least one light-emitting element are projected onto the light-guiding unit, then the light beams are guided to project onto an object that is disposed on the light-transmitting area of the cover unit by the light-guiding unit, next the light beams are reflected by the object to form a reflected light beams that are projected onto the optical imaging element, and then the reflected light beams pass through the optical image unit and the light-transmitting substrate unit and project onto the image-sensing area of the at least one image-capturing element.

2. The flip-chip type image-capturing module according to claim 1, wherein the light-transmitting substrate unit has a light-transmitting substrate and a plurality of conductive circuits disposed on the light-transmitting substrate, and the at least one image-capturing element and the at least one light-emitting element electrically connected to the conductive circuits.

3. The flip-chip type image-capturing module according to claim 1, wherein the optical imaging unit has a shading body positioned on the top surface of the light-transmitting substrate unit and a condensing element jointed with the shading body and disposed above the at least one image-capturing element.

4. The flip-chip type image-capturing module according to claim 3, wherein the shading body of the optical imaging unit has a shading plate inserted into the light-transmitting substrate unit in order to prevent the light beams generated by the at least one light-emitting element from passing through the light-transmitting substrate unit to be guided to the at least one image-capturing element directly.

5. The flip-chip type image-capturing module according to claim 3, wherein the light-transmitting area of the cover unit is a light-transmitting element disposed above the condensing element and the object is disposed on the light-transmitting element, and the cover unit has a reflecting layer formed on an inner surface thereof.

6. The flip-chip type image-capturing module according to claim 1, wherein the at least one light-emitting element is electrically disposed on the top surface of the light-transmitting substrate unit, and the conductive elements are solder balls.

7. The flip-chip type image-capturing module according to claim 1, wherein the at least one light-emitting element is electrically disposed on the bottom surface of the light-transmitting substrate unit by another conductive elements, so that the light beams generated from the light-emitting area of the at least one light-emitting element pass through the light-transmitting substrate unit to project onto the light-guiding unit.

8. A flip-chip type image-capturing module, comprising:
a non-light-transmitting substrate unit having at least one first opening;
an image-capturing unit having at least one image-capturing element electrically disposed on a bottom surface of the non-light-transmitting substrate unit by a plurality of conductive elements, wherein the at least one image-capturing element has an image-sensing area formed on a top surface thereof and facing the at least one first opening;
an optical imaging unit disposed on a top surface of the non-light-transmitting substrate unit and above the at least one image-capturing element;
a light-guiding unit disposed on the top surface of the non-light-transmitting substrate unit and covering the optical imaging unit;
a light-emitting unit having at least one light-emitting element electrically disposed on the non-light-transmitting substrate unit, wherein the at least one light-emitting element has a light-emitting area facing the light-guiding unit; and
a cover unit disposed on the top surface of the non-light-transmitting substrate unit and covering the light-guiding unit, wherein the cover unit has a non-light-transmitting area formed on a top side thereof and above the at least one image-capturing element;
whereby, light beams generated from the light-emitting area of the at least one light-emitting element are projected onto the light-guiding unit, then the light beams are guided to project onto an object that is disposed on the non-light-transmitting area of the cover unit by the light-guiding unit, next the light beams are reflected by the object to form a reflected light beams that are projected onto the optical imaging element, and then the reflected light beams pass through the optical image unit and the at least one first opening of the non-light-transmitting substrate unit and project onto the image-sensing area of the at least one image-capturing element.

9. The flip-chip type image-capturing module according to claim 8, wherein the non-light-transmitting substrate unit has a non-light-transmitting substrate and a plurality of conductive circuits disposed on the non-light-transmitting substrate, and the at least one image-capturing element and the at least one light-emitting element electrically connected to the conductive circuits.

10. The flip-chip type image-capturing module according to claim 8, wherein the optical imaging unit has a shading body positioned on the top surface of the non-light-transmitting substrate unit and a condensing element jointed with the shading body and disposed above the at least one image-capturing element.

11. The flip-chip type image-capturing module according to claim 10, wherein the non-light-transmitting area of the cover unit is a non-light-transmitting element disposed above the condensing element and the object is disposed on the non-light-transmitting element, and the cover unit has a reflecting layer formed on an inner surface thereof.

12. The flip-chip type image-capturing module according to claim 8, wherein the at least one light-emitting element is electrically disposed on the top surface of the non-light-transmitting substrate unit, and the conductive elements are solder balls.

13. The flip-chip type image-capturing module according to claim 8, wherein the non-light-transmitting substrate unit has at least one second opening, the at least one light-emitting element is electrically disposed on the bottom surface of the non-light-transmitting substrate unit by another conductive elements, and the light-emitting area of the at least one light-emitting element faces the at least one second opening of the non-light-transmitting substrate unit, so that the light beams generated from the light-emitting area of the at least one light-emitting element pass through the at least one second opening of the non-light-transmitting substrate unit to project onto the light-guiding unit.

14. A flip-chip type image-capturing module, comprising:
a light-transmitting substrate unit;
an image-capturing unit having at least one image-capturing element electrically disposed on a bottom surface of the light-transmitting substrate unit by a plurality of conductive elements, wherein the at least one image-capturing element has an image-sensing area formed on a top surface thereof and facing the light-transmitting substrate unit;
a light-emitting unit having at least one light-emitting element electrically disposed on the light-transmitting substrate unit; and
a light beam guiding unit disposed on the top surface of the light-transmitting substrate unit, wherein an object is disposed on the light beam guiding unit, and the light beam guiding unit has a light beam guiding structure for guiding light beams generated by the at least one light-emitting element to a bottom portion of the object and the image-sensing area of the at least one image-capturing element in sequence.

15. The flip-chip type image-capturing module according to claim 14, wherein the light beam guiding unit comprises:
an optical imaging unit disposed on a top surface of the light-transmitting substrate unit and above the at least one image-capturing element;
a light-guiding unit disposed on the top surface of the light-transmitting substrate unit and covering the optical imaging unit, wherein the at least one light-emitting element has a light-emitting area facing the light-guiding unit; and
a cover unit disposed on the top surface of the light-transmitting substrate unit and covering the light-guiding unit, wherein the cover unit has a light-transmitting area formed on a top side thereof and above the at least one image-capturing element;
whereby, light beams generated from the light-emitting area of the at least one light-emitting element are projected onto the light-guiding unit, then the light beams are guided to project onto an object that is disposed on the light-transmitting area of the cover unit by the light-guiding unit, next the light beams are reflected by the object to form a reflected light beams that are projected onto the optical imaging element, and then the reflected light beams pass through the optical image unit and the light-transmitting substrate unit and project onto the image-sensing area of the at least one image-capturing element.

16. The flip-chip type image-capturing module according to claim 15, wherein the optical imaging unit has a shading body positioned on the top surface of the light-transmitting substrate unit and a condensing element jointed with the shading body and disposed above the at least one image-capturing element.

17. The flip-chip type image-capturing module according to claim 16, wherein the shading body of the optical imaging unit has a shading plate inserted into the light-transmitting substrate unit in order to prevent the light beams generated by the at least one light-emitting element from passing through the light-transmitting substrate unit to be guided to the at least one image-capturing element directly.

18. The flip-chip type image-capturing module according to claim 16, wherein the light-transmitting area of the cover unit is a light-transmitting element disposed above the condensing element and the object is disposed on the light-transmitting element, and the cover unit has a reflecting layer formed on an inner surface thereof.

19. The flip-chip type image-capturing module according to claim 14, wherein the light-transmitting substrate unit has a light-transmitting substrate and a plurality of conductive circuits disposed on the light-transmitting substrate, the at least one image-capturing element and the at least one light-emitting element electrically connected to the conductive circuits, the at least one light-emitting element is electrically disposed on the top surface of the light-transmitting substrate unit, the at least one light-emitting element has a light-emitting area facing the light beam guiding structure, and the conductive elements are solder balls.

20. The flip-chip type image-capturing module according to claim 14, wherein the at least one light-emitting element is electrically disposed on the bottom surface of the light-transmitting substrate unit by another conductive elements, so that the light beams generated from the light-emitting area of the at least one light-emitting element pass through the light-transmitting substrate unit to project onto the light beam guiding structure.
